(19) United States
(12) Patent Application Publication
(10) Pub. No.: US 2010/0224912 A1
(43) Pub. Date: Sep. 9, 2010

(54) Chromium doped diamond-like carbon

(76) Inventors: Varshni Singh, Baton Rouge, LA (US); Peter Dowben, Crete, NE (US); Ihor Ketsman, Lincoln, NE (US); Juan Colon-Santana, Lincoln, NE (US); Yaroslav Losovyj, Baton Rouge, LA (US); Vadim Palshin, Baton Rouge, LA (US)

Correspondence Address: Adams and Reese LLP, 1221 McKinney Street, Suite 4400, Houston, TX, 77010, US

(21) Appl. No.: 12/590,524

(22) Filed: Nov. 10, 2009

Related U.S. Application Data
(60) Provisional application No. 61/198,790, filed on Nov. 10, 2008.

(51) Int. Cl. H01L 29/12; H01L 21/20

(52) U.S. Cl. 257/201; 438/508; 257/613; 257/E29.068; 257/E21.09

(57) ABSTRACT

A heterojunction is provided for spin electronics applications. The heterojunction includes an n-type silicon semiconductor and a hydrogenated diamond-like carbon film deposited on the n-type silicon semiconductor. The hydrogenated diamond-like carbon film is doped with chromium. The concentration of the chromium dopant in the chromium doped diamond-like carbon film may be configured such that the heterojunction has an increase in forward bias current ranging from about 50% to about 150% in a small magnetic field at about room temperature. The heterojunction has spin electronics properties at about room temperature.

### CROSS-REFERENCE TO RELATED APPLICATIONS

This application claims the benefit of U.S. Provisional Patent Application Ser. No. 61/198,790 filed Nov. 10, 2008 which is expressly incorporated herein in its entirety by reference thereto.

### STATEMENT OF GOVERNMENT-SPONSORED RESEARCH

This invention was made with government support under the following contracts:
Contract DAAG55-98-1-0279, from the U.S. Army/Army Research Office;
Contract ECS0725881, from the National Science Foundation; and
Contract N00014-06-1-0616, from the U.S. Navy/Office of Naval Research.
   The government has certain rights in the invention.

### FIELD

The present invention relates generally to spin-electronics applications and particularly to Chromium (Cr) doped diamond-like carbon (“DLC”) films as semiconductor spintronics materials and methods to create semiconductors for spin electronics applications.

### BACKGROUND

DLC films have been extensively studied for over a decade due to their unique combination of chemical inertness, mechanical, tribological and optical properties. Particularly, composite metal-containing DLC films have gained popularity in the scientific community, as metal additions allow controllable variation of a wide variety of properties ranging from electrical conductivity, optical and magnetic to mechanical and tribological. Therefore, these composites are important multifunctional materials for applications where mechanical integrity, low friction, and/or high wear resistance are required, such as electronic, micro-electromechanical, magnetic, and photonic applications.

While the use of DLC films and metal-containing composites thereof has been researched in fields where hardness and tribological properties are key, such as corrosive and wear resistant coatings for tools and sharp instruments, little research has been devoted to the use of these materials as semiconductors, and particularly the emerging field of spin electronics (“spintronics”). Spintronics or semiconductor spintronics is an area of semiconductor electronics where spin degrees of freedom play an important role in realizing functionalities. Conventional electronics rely on the transport of electrons (and the detection of such) in a semiconductor such as silicon. Individual electrons possess an intrinsic angular momentum (“electron spin”) and a magnetic moment which is oriented in either an “up” or “down” direction. In the field of spintronics, devices exploit the spin of electrons to store/write information as a particular spin orientation (i.e., “up” or “down”). The ability to store additional information in the spin orientation of a flow of electrons makes such devices particularly attractive in the area of quantum computing/quantum information technologies, where the electron spin can represent an extra “bit” (called a “qubit”) of information, and in the area on information storage devices and the reduction of the footprints thereof. Most currently available spintronic technologies utilize materials that demonstrate such properties only at temperatures below room temperature.

### SUMMARY

According to an exemplary embodiment of the present invention, a heterojunction for use in spin electronics applications is provided that includes an n-type silicon semiconductor and a chromium doped hydrogenated diamond-like carbon film deposited on the n-type silicon semiconductor. The concentration of chromium dopant may be configured such that the heterojunction has an increase in forward bias current ranging from about 50% to about 150% in a small magnetic field at about room temperature and such that the heterojunction has spin electronic properties at about room temperature.

### BRIEF DESCRIPTION OF THE DRAWINGS

FIG. 1 is a cross-section of a heterojunction comprising a Cr doped DLC film deposited on an n-type silicon semiconductor, according to an exemplary embodiment of the present invention.

FIG. 2(a) illustrates X-ray absorption edge structure spectra of Cr-DLC films, Cr and Cr₃C₂, normalized spectra, translated along the y-axis (intensity) according to exemplary embodiments of the present invention.

FIG. 2(b) illustrates the Fourier transform of the EXAFS spectra for the Cr-DLC films along with pure Cr carbide (Cr₃C₂) according to exemplary embodiments of the present invention.

FIG. 3(a) illustrates magnetization curves of Cr-DLC (˜3% at Cr) at 20 K, including the virgin magnetization curve, according to exemplary embodiment of the present invention.

FIG. 3(b) illustrates magnetization curves of Cr-DLC (˜3% at Cr) at 10K, including the virgin magnetization curve, according to exemplary embodiments of the present invention.

FIG. 4(a) illustrates the I-V curves for a 11 at % Cr Cr-DLC film to n-type silicon heterojunction device with changing applied magnetic field, at room temperature, according to an exemplary embodiment of the present invention.

FIG. 4(b) illustrates the I-V curves for a 15 at % Cr Cr-DLC film to n-type silicon heterojunction device with changing applied magnetic field, at room temperature, according to an exemplary embodiment of the present invention.

FIG. 4(c) illustrates the change in forward current, as a function of the magnetic field, plotted for a forward bias of 2V, for a Cr-DLC film to n-type silicon heterojunction device at about 11.0% Cr, according to an exemplary embodiment of the present invention.

FIG. 4(d) illustrates the change in forward current, as a function of the magnetic field, plotted for a forward bias of 2V, for a Cr-DLC film to n-type silicon heterojunction device at about 15.0% Cr, according to an exemplary embodiment of the present invention.

### DETAILED DESCRIPTION

Embodiments of the present invention are provided that exploit the magnetic properties of Cr and Cr doped DLC to yield spintronic properties, such as increased coupling of magnetic moments, at room temperature. Heterojunction devices may be provided that include Cr-DLC films deposited on n-type silicon in which various concentrations of chromium acted as a p-type dopant to the DLC films. At low Cr concentrations, both ferromagnetic and compensated magnetic coupling occur in the Cr-DLC films at low temperatures. In a wide range of Cr concentrations up to 18%, the Cr-DLC films form a heterojunction with the n-type silicon that demonstrated a large coefficient of negative magnetoresistance at room temperature. Embodiments of the present invention may be applied to several different commercial applications, including quantum computers/quantum information technologies, medical devices, ferromagnetic semiconductors, magneto-optic devices, magnetoresistive devices, and information storage devices.

In accordance with embodiments of the present invention, the functionality and application of amorphous DLC films are extended by metal additions, which have a profound effect on the films. Cr in combination with DLC increases coupling of magnetic moments, making the composite attractive for spintronics applications.

In accordance with embodiments of the present invention, Cr doped DLC films are provided that have significant advantages in tribological applications due to their high hardness and low friction coefficient. Further, according to embodiments of the present invention, DLC films are provided with properties that make them suitable for solar cell applications. Still further, in accordance with embodiments of the present invention, Cr doped DLC films have unique magnetic properties and possess spintronics properties at room temperature that make them very attractive for commercial applications.

Embodiments of the inventive subject matter utilize Cr-doped hydrogenated diamond-like carbon (Cr-DLC) and chromium carbide hydrogenated diamond-like carbon alloys, which are provided as a mixed matrix material and in the form of heterojunctions for spin-electronics applications.

In certain embodiments of the present invention, chromium-doped hydrogenated diamond-like carbon and chromium carbide hydrogenated diamond-like carbon alloys may be synthesized by plasma-assisted vapor deposition and investigated by such techniques as X-Ray Absorption Near Edge Structure (XANES), Extended X-Ray Absorption Fine Structure (EXAFS), Synchrotron Radiation VUV Photoelectron Spectroscopy, Superconducting Quantum Interference Device (SQUID) magnetometry, I-V curve measurements, and magnetoresistance.

Structural and magnetic properties of the doped and alloy materials may be altered as a function of the Cr concentration, which may vary from about 0.1% to about 20%. At low concentration, Cr substitutes for carbon in a diamond-like amorphous matrix and forms a substitutional solid-solution compound. Towards the upper end of the concentration range, the Cr precipitates in the form of chromium carbide (Cr₃C₂) nanoclusters. For low Cr concentrations, the systems are ferromagnetic at very low temperatures, whereas the chromium-carbide clusters formed at higher concentrations are antiferromagnetic with uncompensated spins at the surface. Cr-DLC films and alloys with various Cr concentrations may be used to make heterojunctions on silicon, and the produced diodes may be investigated by I-V measurements. The heterojunctions exhibit negative magnetoresistance that saturates at less than 500 Oe and may be suitable for spin-electronics applications.

The unique features of Cr-doped DLC films is not limited to the field of spintronics. Embodiments of the present invention may be used in any field where materials featuring an adjustable bandgap are desired, such as solar energy applications. While DLC films' large bandgap renders them generally unsuitable for photoelectric cell applications, according to embodiments of the present invention the bandgap of Cr-doped DLC films may be engineered/modified/decreased by Cr addition up to 20%. Modulated-bandgap DLC films may be desirable for solar energy harvesting, as a sufficiently low gap will permit relatively low-energy photons to excite electrons into the conduction band. Suitable substrates for the Cr-doped DLC films intended for solar energy harvesting are thus not restricted to doped or pure semiconductor materials; indeed, substrates may be selected from metals.

Embodiments of a hybrid plasma-assisted PVD/CVD process may be used to deposit the Cr-DLC films onto a Si(100) substrate. Embodiments of the process may involve magnetron sputtering from a Cr target (99.5% Cr) in an Ar/CH₄ discharge with the substrate biased at −1000 V. Further embodiments include varying the Cr content in the Cr-DLC by operating the magnetron under current control and modulating the current between 100 mA and 350 mA. In other embodiments, Cr-DLC films with variable levels of Cr concentrate are embedded in an amorphous matrix, which forms crystalline nanoclusters ranging from about 2 nm to about 5 nm in size. In still other embodiments, Cr-DLC films with a Cr concentration of less than or equal to about 0.4% the atomic clusters are not formed because Cr is dissolved in the DLC matrix. To determine the chromium content, some embodiments utilize wavelength-dispersive spectroscopy (WDS) or energy dispersive spectroscopy (EDS). In addition, the X-ray absorption (EXAFS and XANES) spectroscopies can determine the structure of embodiments of the Cr-DLC films.

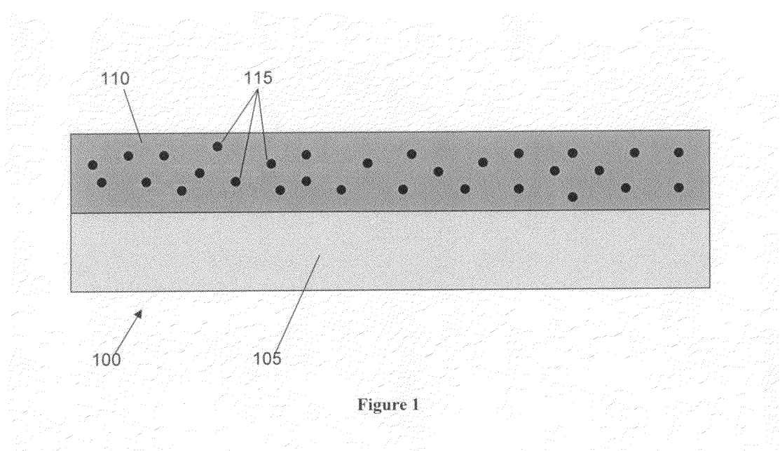

FIG. 1 shows a cross section of a heterojunction 100 according to an exemplary embodiment of the present invention. The heterojunction 100 includes an n-type silicon semiconductor 105 and a DLC film 110 deposited on the silicon semiconductor 105. The DLC film 110 is doped with Cr 115, which acts as a p-type dopant.

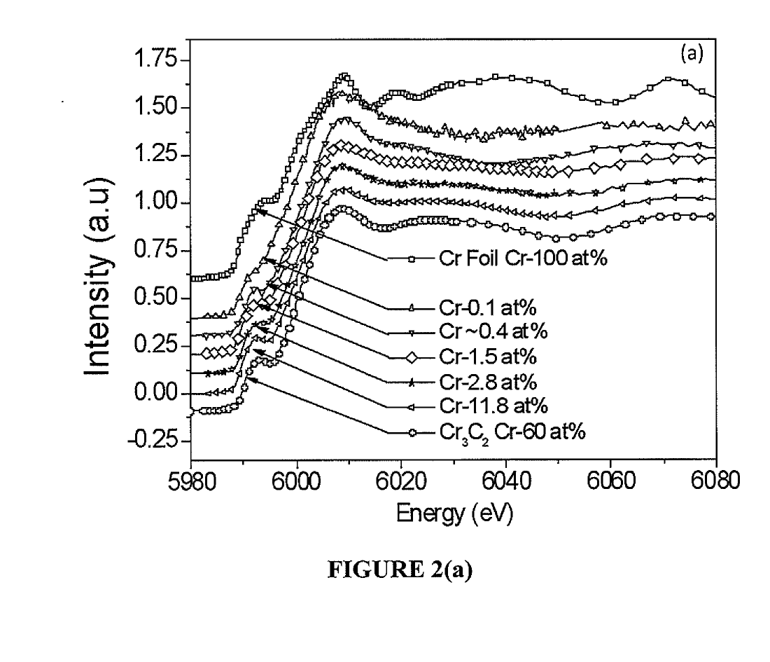

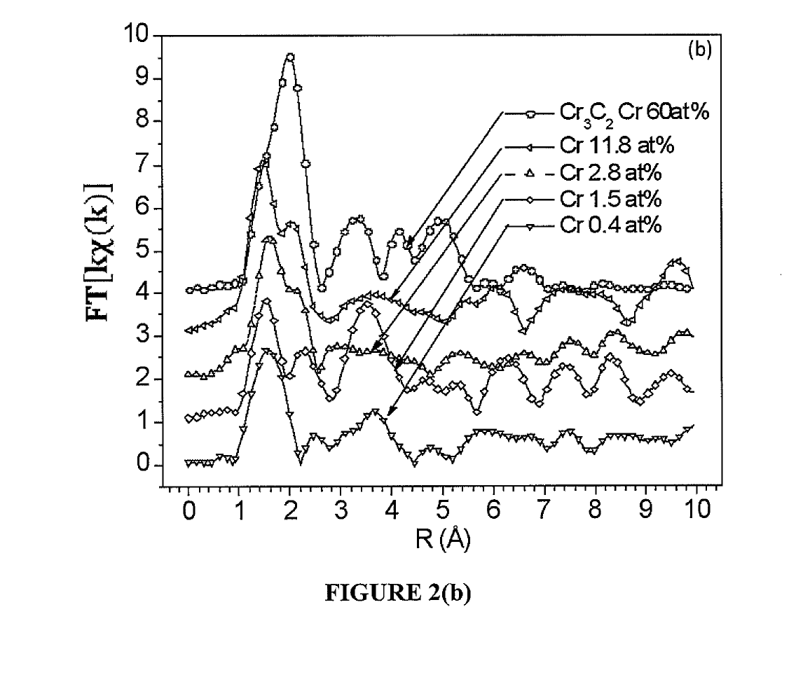

FIG. 2(a) shows X-ray absorption edge structure spectra of Cr-DLC films, Cr and Cr₃C₂, normalized spectra, translated along the y-axis (intensity). XANES spectra were obtained for certain embodiments of the present invention containing Cr contents of about 0.1%, 0.4%, 1.5%, 2.8% and about 11.8% along with pure Cr, Cr-III oxide (Cr₂O₂) and Cr carbide (Cr₃C₂) samples. (All concentrations were measured in %). The XANES spectra indicate that the chemical state and the local environment around the absorbing Cr atoms remains essentially the same for Cr content higher than or comparable greater than or equal to 1.5%. In this concentration range, the XANES spectra of the films are reminiscent of Cr₃C₂ spectrum, and the high Cr concentrations yield nanocluster precipitates, similar to the situation encountered in Co-DLC and Ti-DLC systems. For low Cr concentrations (about 0.4% and about 0.1%), the local environment about Cr was significantly enhanced and reduced C and Cr coordination numbers, respectively. For instance, in the sample with about 0.4% Cr, each chromium atom has 6.6±0.7 C and 2.0±0.9 Cr neighbors, as compared to the respective numbers 4 and 11 for Cr₃C₂. This is consistent with a solid solution of Cr in C, with little clustering of Cr. Some clustering can not be excluded, because the strain created by the substitution of Cr for C yields an attractive interaction (Kanzaki forces) between the Cr atoms, similar to the situation encountered for gases in metals. Thus, clustering of chromium impurities typically occur for concentrations exceeding about 1.5%. However, uniform Cr distribution in C matrix at lower levels (about 6%) and Cr-rich cluster formation at high doping levels of about 12% may occur.

FIG. 2(b) depicts the Fourier-transformed EXAFS spectra of Cr-carbide and Cr-DLC films at the Cr K-edge, according to certain embodiments of the present invention. The spectra of the films with high Cr content (11.8 and 2.8%) show two peaks (1.5 and 2.1 Å) corresponding to the two sub-shells (Cr . . . 0 and Cr . . . Cr) of the first coordination shell. The data also suggest a highly disordered (amorphous) structure with some short-range order because no significant features were observed above 2.6 Å. Similar observations were made on these films by X-ray diffraction and low angle X-ray diffraction experiments. Further, the bond lengths are nearly the same for all films and similar to that of Cr₃C₂ powder (2.2 Å for Cr—C and 2.7 Å for Cr—Cr). Based on both valence band and core level photoemission more pronounced precipitation of carbide nanoclusters occurs at the surface than in the bulk, which is important for spintronics applications.

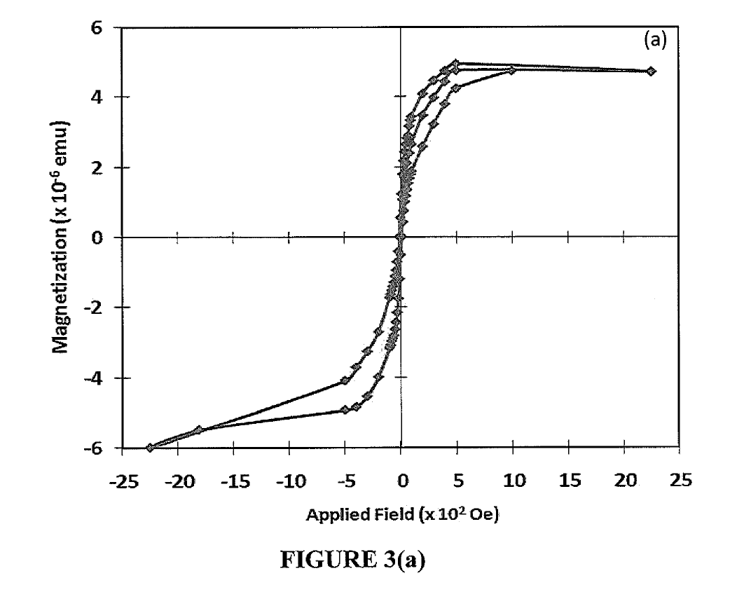

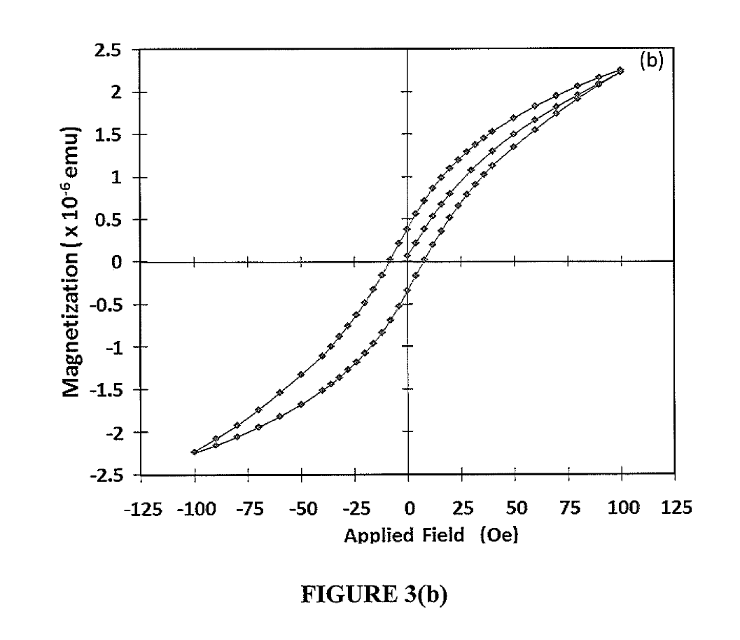

FIGS. 3(a) and 3(b) show the magnetization curves of Cr-DLC films with about 3% chromium at 20K and 10K, respectively, according to certain embodiments of the present invention. Superconducting Quantum Interference Device (SQUID) magnetometry was used to perform the magnetic measurements, which were performed with the magnetic field in the film plane. At low temperatures of about 10K, the curves show ferromagnetisms, but at higher temperatures (above 20K) the curves indicate compensated ferromagnetism. Constricted loops frequently occur in magnetically inhomogeneous systems and reflect a cluster-size distribution ranging from very few interatomic distances to about 10 nm.

Exchange interactions leading to Curie temperatures above 20 K are common in magnetic oxides and not surprising where the C 2p electrons strongly hybridize with the Cr 3d electrons. In fact, the strong overlap between 2p electron-orbitals in elements such as B, C, and O means that 2p moment created by transition-metal ions and other impurities couple relatively rigidly to neighboring 2p atoms. Relatively extended orbitals of this type occur in some oxides and Co doped semiconducting boron carbides.

The largely carbon-weighted photoemission features at 6 eV are enhanced at photon energies of about 39-44 eV, near the Cr 3p band (42 eV), and the chromium 3d bands are strongly hybridized to the carbon 2p. This hybridization provides for the low-temperature ferromagnetism of the dilute Cr-DLC. Below 12 K, the system exhibits ordinary hysteresis loops, with a coercivity of order 0.8 mT (8 Oe), but at somewhat elevated temperatures (above 20 K), the hysteresis loops are constricted (wasp-like).

Cr-DLC heterojunctions with silicon may be fabricated for spin-electronics applications. According to exemplary embodiments of the present invention, devices may be produced that include Cr-DLC films deposited on n-type silicon in which various concentrations of chromium act as a p-type dopant to the DLC films. According to certain embodiments of the present invention, such a heterojunction device may have about 50% to about 150% increases in forward bias currents in a small magnetic field. According to further embodiments, Cr-doped hydrogenated diamond-like carbon and chromium carbide hydrogenated diamond-like carbon alloys are provided where, in the film embodiments of higher chromium concentration, a large coefficient of negative magneto-resistance is provided in heterojunction devices with n-type silicon. Therefore, embodiments of the present invention may provide significant functionality over other conventional heterojunction diodes.

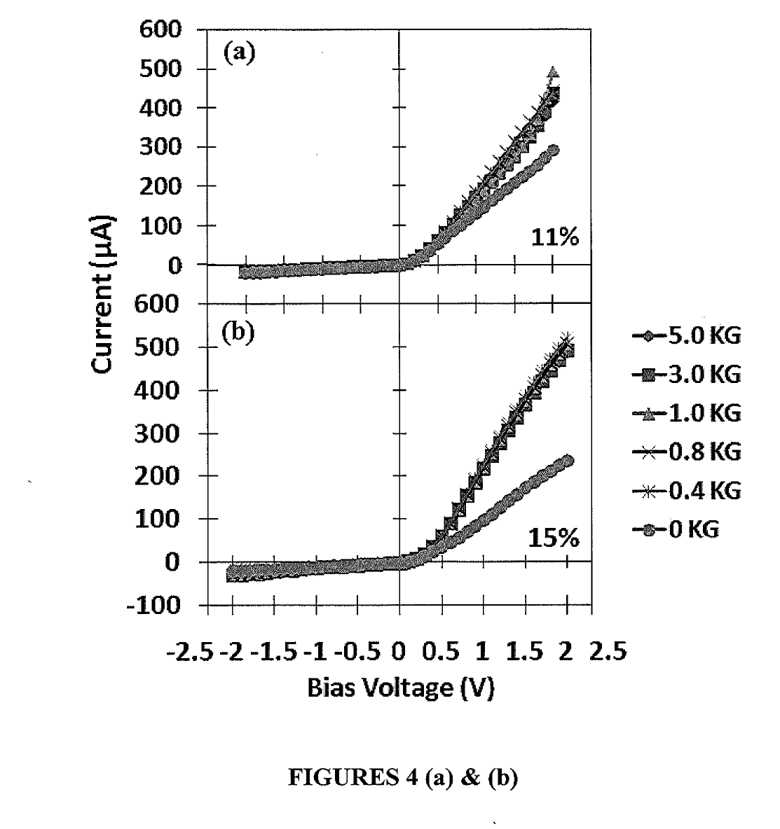

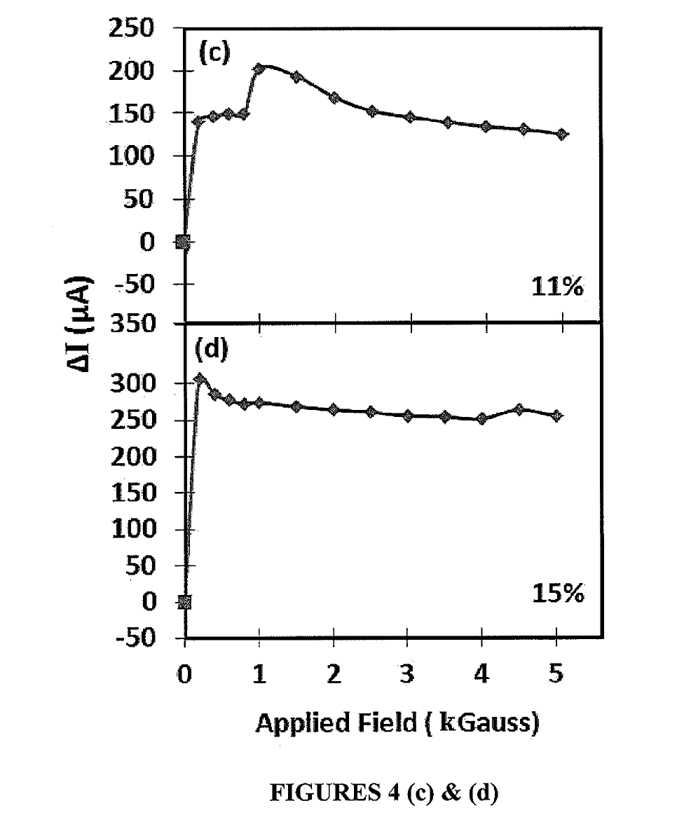

FIGS. 4(a) and 4(b) show the I-V curves for heterojunctions made with about 11% Cr and about 15% Cr content, respectively, with a changing applied magnetic field at room temperature, according to exemplary embodiments of the present invention. At lower doping levels, heterojunction diodes were made, but the capacitance was quite large and dominated the devices properties, consistent with amorphous carbon films on n-type silicon. As shown in FIGS. 3(a) and 3(b), good diode rectification may be obtained for about 11% to about 15% Cr doping. With a Cr doping concentration of about 20% or more, heterojunction diodes with n-type silicon may show very large relative leakage currents in reverse bias and increasingly resemble a ‘bad’ conventional resistor. The negative magnetoresistance of the I-V curve, which is ascribed to uncompensated spins at the surface of the antiferromagnetic chromium-carbide clusters, indicates that embodiments of present invention are suitable for spin-electronics applications.

FIGS. 4(c) and 4(d) show the change in forward current as a function of the magnetic field, plotted for a forward bias of 2V, for Cr-DLC film to n-type silicon heterojunction devices at about 11.0% Cr and 15.0% Cr, respectively, according to exemplary embodiments of the present invention. The heterojunction diodes of n-type silicon and about 11% and about 15% Cr-doped DLC films as the p-type semiconductor have strong negative magnetoresistance with the forward bias current increasing with magnetic field, even at room temperature. At 2 V forward bias, the negative magneto-resistance may be as much as about 50% to about 100% in an applied magnetic field as small as 300 Oe. Due to magnetic ordering, the negative magnetoresistance saturates and shows little change at the higher applied magnetic fields. Accordingly, antiferromagnetic order creates uncompensated spins at the clusters' surfaces. These cluster macrospins interact with each other, since the clusters are particularly concentrated at the DLC film surface, with the magnetic field, and with an electric current.

Embodiments of the present invention apply to, but are not limited to the following applications of semiconductor spintronics:
Quantum information technologies using spin as a qubit in solid state
Medical applications
Ferromagnetic semiconductors
Magneto-optic devices
Magneto-resistive devices
Spin coherence
   These applications, and others that utilize embodiments of Cr doped DLC film as a semiconductor spintronics material, will achieve the desired spintronics properties at room temperature in addition to below room temperatures.

While the embodiments are described with reference to various implementations and exploitations, it will be understood that these embodiments are illustrative and that the scope of the inventions is not limited to them. Many variations, modifications, additions, and improvements are possible. Further still, any steps described herein may be carried out in any desired order, and any desired steps may be added or deleted.

What is claimed is:

1. A heterojunction for use in spin electronics applications, comprising:
an n-type silicon semiconductor; and
a hydrogenated diamond-like carbon film deposited on the n-type silicon semiconductor,
wherein the hydrogenated diamond-like carbon film is doped with chromium; and
wherein the concentration of chromium in the chromium doped diamond-like carbon film is configured such that the heterojunction has an increase in forward bias current ranging from about 50% to about 150% in a small magnetic field at about room temperature and the heterojunction has spin electronic properties at about room temperature.

2. A heterojunction for use in spin electronics applications, comprising:
an n-type silicon semiconductor; and
a hydrogenated diamond-like carbon film deposited on the n-type silicon semiconductor,
wherein the hydrogenated diamond-like carbon film is doped with chromium.

3. The heterojunction of claim 2, wherein the concentration of chromium in the chromium doped diamond-like carbon film is from about 5% to about 20%.

4. The heterojunction of claim 2, wherein the concentration of chromium in the chromium doped diamond-like carbon film is configured such that the heterojunction has an increase in forward bias current ranging from about 50% to about 150% in a small magnetic field at room temperature.

5. The heterojunction of claim 4, wherein the small magnetic field is no greater than 3 kGauss.

6. The heterojunction of claim 2, wherein the concentration of chromium in the chromium doped diamond-like carbon film is configured such that the heterojunction has spin electronic properties at about room temperature.

7. A heterojunction for use in spin electronics applications, comprising:
an n-type silicon semiconductor; and
a chromium carbide hydrogenated diamond-like carbon alloy deposited on the n-type silicon semiconductor.

8. The heterojunction of claim 7, wherein the concentration of chromium in the chromium carbide hydrogenated diamond-like carbon alloy is from about 5% to about 20%.

9. The heterojunction of claim 7, wherein the chromium carbide hydrogenated diamond-like carbon alloy is configured such that the heterojunction has an increase in forward bias current ranging from about 50% to about 150% in a small magnetic field at room temperature.

10. The heterojunction of claim 9, wherein the small magnetic field is no greater than 3 kGauss.

11. A heterojunction for use in spin electronics applications, comprising:
an n-type silicon semiconductor; and
a metal containing hydrogenated diamond-like carbon film deposited on the n-type silicon semiconductor,
wherein the metal is configured to act as a p-type dopant.

12. The heterojunction of claim 11, wherein the concentration of metal dopant in the metal containing diamond-like carbon film is configured such that the heterojunction has an increase in forward bias current ranging from about 50% to about 150% in a small magnetic field at room temperature.

13. The heterojunction of claim 12, wherein the small magnetic field is no greater than 3 kGauss.

14. The heterojunction of claim 11, wherein the concentration of metal dopant in the metal containing diamond-like carbon film is configured such that the heterojunction has spin electronic properties at about room temperature.

15. A method for making a heterojunction for use in spin electronics applications, comprising: using a hybrid plasma-assisted PVD/CVD to deposit the Cr-DLC films onto a Si(100) substrate, wherein Cr doping is achieved via magnetron sputtering from a Cr target (99.5% Cr) in an Ar/CH₄ discharge with the substrate biased at −1000 V.

16. The method of claim 15, wherein the Cr content in the Cr-DLC is varied by operating the magnetron under current control and modulating the current between 100 mA and 350 mA.

17. An apparatus, comprising:
a Cr-doped DLC film configured to have an adjustable bandgap, wherein the concentration of Cr in the Cr-doped DLC film is configured such that a change in the concentration of Cr yields a corresponding change in the DLC film bandgap; and
a substrate.

18. The apparatus of claim 17, wherein the Cr concentration is from about 0.1% to about 20%.

19. The apparatus of claim 17, wherein the substrate includes at least one of a metal, a semiconductor and a doped semiconductor.
